(19) United States
(12) Patent Application Publication
(10) Pub. No.: US 2012/0035874 A1
(43) Pub. Date: Feb. 9, 2012

(54) BATTERY PACK AND METHOD OF CONTROLLING THE SAME

(76) Inventors: Han-Seok Yun, Yongin-si (KR); Segawa Susumu, Yongin-si (KR); Eui-Jeong Hwang, Yongin-si (KR); Se-Sub Sim, Yongin-si (KR); Jong-Woon Yang, Yongin-si (KR); Beom-Gyu Kim, Yongin-si (KR); Jin-Wan Kim, Yongin-si (KR)

(21) Appl. No.: 13/037,020

(22) Filed: Feb. 28, 2011

(30) Foreign Application Priority Data
Aug. 6, 2010 (KR) 10-2010-0075988

(51) Int. Cl. G06F 19/00; G01R 31/02

(52) U.S. Cl. 702/64; 324/537

(57) ABSTRACT

A battery pack includes a battery cell; a protective circuit for protecting the battery cell; a first analog/digital (A/D) converter for converting a voltage of the battery cell into a digital value and outputting the digital value as a first voltage value; a second A/D converter for converting the voltage of the battery cell into another digital value and outputting the another digital value as a second voltage value; and a comparator for comparing the first voltage value with the second voltage value and determining whether A/D conversion of the battery pack is normal or defective according to the comparison.

### CROSS-REFERENCE TO RELATED APPLICATIONS

This application claims the benefit of Korean Patent Application No. 10-2010-0075988, filed on Aug. 6, 2010, in the Korean Intellectual Property Office, the disclosure of which is incorporated herein in its entirety by reference.

### BACKGROUND

1. Field

One or more embodiments of the present invention relate to a battery pack and a method of controlling the battery pack.

2. Description of Related Art

Research on rechargeable batteries is being actively conducted for applications in, for example, portable electronic devices such as cellular phones, notebook computers, camcorders, and personal digital assistants (PDAs). In particular, there are various kinds of secondary batteries, for example, nickel-cadmium batteries, lead batteries, nickel metal hydride (NiMH) batteries, lithium ion batteries, lithium polymer batteries, metal lithium batteries, and zinc-air batteries. Secondary batteries are combined with a circuit to configure a battery pack, and charging and discharging of the secondary batteries are performed through an external terminal of the battery pack.

A conventional battery pack includes a battery cell and a peripheral circuit including a charging-discharging circuit. The peripheral circuit is fabricated as a printed circuit board and combined with the battery cell. When an external power source is connected to an external terminal of the battery pack, the battery cell is charged by external power supplied through the external terminal and the charging-discharging circuit. In addition, when a load is connected to the external terminal, power from the battery cell is supplied to the load through the charging-discharging circuit and the external circuit. Here, the charging-discharging circuit controls the charging and discharging of the battery cell between the external terminal and the battery cell. In general, a plurality of battery cells are connected in series or in parallel according to a power consumption amount/rate of the load.

### SUMMARY OF THE INVENTION

One or more embodiments of the present invention include a battery pack that may determine whether an analog-digital conversion in the battery pack is performed normally.

Additional aspects will be set forth in part in the description which follows and will be apparent from the description, or may be learned by practice of the presented embodiments.

According to one or more embodiments of the present invention, a battery pack includes: a battery cell; a protective circuit for protecting the battery cell; a first analog/digital (A/D) converter for converting a voltage of the battery cell into a digital value and outputting the digital value as a first voltage value; a second A/D converter for converting the voltage of the battery cell into another digital value and outputting the another digital value as a second voltage value; and a comparator for comparing the first voltage value with the second voltage value and determining whether A/D conversion of the battery pack is normal or defective according to the comparison.

The comparator may be configured to determine that the A/D conversion is defective when a difference between the first voltage value and the second voltage value is equal to or greater than a threshold value.

The protective circuit may include: an analog front end (AFE) connected to the battery cell; a computing device; and a charging switch and a discharging switch respectively turned on or turned off according to control by the computing device.

The computing device may include: the first A/D converter for converting the voltage of the battery cell output from the AFE into the digital value and outputting the digital value as the first voltage value; and the comparator for comparing the first voltage value output from the first A/D converter with the second voltage value output from the second A/D converter to determine whether the A/D conversion of the computing device is normal or defective.

The second A/D converter may be configured to convert the voltage of the battery cell output from the AFE into the another digital value and to output the another digital value as the second voltage value to the comparator.

The computing device may further include a control terminal for outputting a control signal indicating a defect in the A/D conversion of the computing device when a difference between the first voltage value and the second voltage value is equal to or greater than a threshold value.

The computing device may be configured to output a control signal for turning off at least one of the charging switch or the discharging switch when a difference between the first voltage value and the second voltage value is equal to or greater than a threshold value.

The battery pack may further include a division resistor for voltage dividing the voltage of the battery cell output from the AFE and outputting the divided voltage to the first A/D converter.

At least two battery cells may be connected in series, and the voltage of the battery cell may include a voltage value of the at least two battery cells.

According to one or more other embodiments of the present invention, a battery pack includes: a plurality of battery cells; an analog front end (AFE) connected to the plurality of battery cells; a computing device; and an A/D converter for converting an input signal from the plurality of battery cells output from the AFE into a digital value, and outputting the digital value as a first output value to the computing device, wherein the computing device compares the first output value with a second output value including another digital value corresponding to the input signal from the plurality of battery cells output from the AFE, to determine whether A/D conversion of the battery pack is normal or defective.

The computing device may be configured to determine that the A/D conversion is defective when a difference between the first output value and the second output value is equal to or greater than a threshold value.

The input signal from the plurality of battery cells may be a voltage of the plurality of battery cells.

According to one or more other embodiments of the present invention, a method for controlling a battery pack including a plurality of battery cells; an AFE connected to the plurality of battery cells; and a computing device, includes: converting an input signal from the plurality of battery cells output from the AFE into a digital value and outputting the digital value as a first output value; converting an input signal from the plurality of battery cells output from the AFE into another digital value and outputting the another digital value as a second output value; comparing the first output value with the second output value; and determining whether A/D conversion of the computing device is normal or defective according to the comparison.

In the determining operation, the A/D conversion may be determined to be defective when a difference between the first output value and the second output value is equal to or greater than a threshold value.

The method may further include: outputting a control signal indicating a defect in the A/D conversion of the computing device when a difference between the first output value and the second output value is equal to or greater than a threshold value.

The control signal may be a signal for turning off at least one of a charging switch or a discharging switch respectively controlling charging and discharging operations of the battery pack.

The input signal from the plurality of battery cells may be a voltage of the plurality of battery cells.

### BRIEF DESCRIPTION OF THE DRAWINGS

These and/or other aspects will become apparent and more readily appreciated from the following description of the embodiments, taken in conjunction with the accompanying drawings, of which:

FIG. 1 is a circuit diagram of a battery pack according to an embodiment of the present invention;

FIG. 2 is a circuit diagram of a battery pack according to another embodiment of the present invention;

FIG. 3 is a circuit diagram of a battery pack according to another embodiment of the present invention; and

FIG. 4 is a flowchart illustrating a method of controlling a battery pack according to an embodiment of the present invention.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described below, with reference to the figures, to explain aspects of the present description.

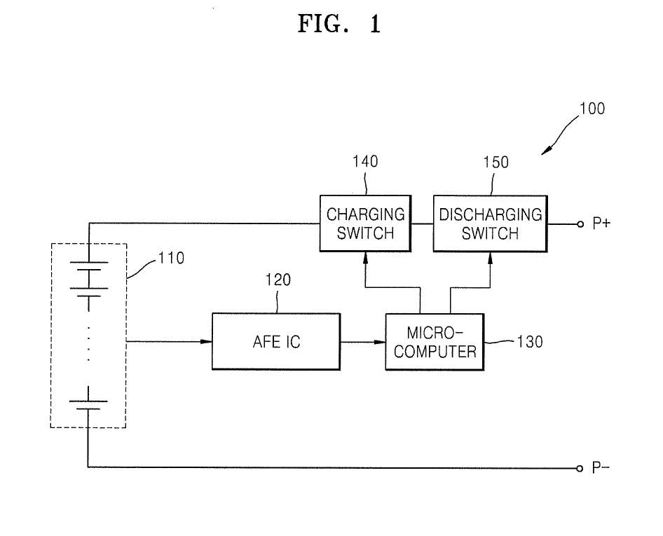

FIG. 1 is a circuit diagram of a battery pack 100 according to an embodiment of the present invention.

Referring to FIG. 1, the battery pack 100 according to the present embodiment includes a rechargeable battery cell 110 and a protective circuit. In addition, the battery pack 100 may be mounted in an external system such as a portable notebook computer to perform charging and discharging operations of the battery cell 110.

The battery pack 100 includes the battery cell 110, an external terminal (not shown) connected to the battery cell 110 in parallel, and a charging switch 140 and a discharging switch 150 connected to a high current path (HCP) in series between the battery cell 110 and the external terminal.

The protective circuit includes an analog front end (AFE) integrated circuit (IC) 120 that is connected to the battery cell 110 in parallel, the charging switch 140 and discharging switch 150, and a micro-computer 130, or similar computing device or processor, connected to the AFE IC 120 and connected to the charging switch 140 and the discharging switch 150. In addition, the protective circuit may further include a fuse (not shown) for blocking the HCP according to a control of the micro-computer 130 or an external system, and a current monitor (not shown) for sensing an amount of current flowing through the HCP.

The micro-computer 130 turns off the charging switch 140 and the discharging switch 150 as described above or melts the fuse to block over-charging and over-discharging of the battery cell 110 when the micro-computer 130 determines that the battery cell 110 is in an over-charged or over-discharged state. That is, when the micro-computer 130 determines that the battery cell 110 is in an over-charged or over-discharged state, the micro-computer 130 outputs a corresponding control signal to blow the fuse through a control switch (not shown) and/or a heater (not shown).

The battery pack 100 configured as described above is connected to an external system through an external terminal to be charged or discharged. The HCP between the external terminal and the battery cell 110 is used as a charging/discharging path, and a large amount of current flows through the HCP. The battery pack 100 may further include a system management bus (SMBUS) between the micro-computer 130 of the protective circuit and the external terminal in order to communicate with the external system.

Here, the external system connected to the battery pack 100 through the external terminal may be a portable electronic device, for example, a portable notebook computer, and may include an additional adaptor for supplying electric power. Thus, when the external system is connected to an adaptor, the external system may be operated via the adaptor, and electric power from the adaptor may be supplied to the battery cell 110 via the external terminal through the HCP to charge the battery cell 110. In addition, when the external system is separated from the adaptor, the battery cell 110 may be discharged by supplying power to a load of the external system through the external terminal. That is, when the external system connected to the adaptor is connected to the external terminal, the charging operation is performed, and the charging path includes the adaptor, the external terminal, the discharging switch 150, the charging switch 140, and the battery cell 110. When the adaptor is separated from the external system, and the load of the external system is connected to the external terminal, the discharging operation is performed, and the discharging path includes the battery cell 110, the charging switch 140, the discharging switch 150, the external terminal, and the load of the external system.

Here, the battery cell 110 is a secondary battery cell that is chargeable and dischargeable. The battery cell 110 outputs various cell-related information, that is, information such as a temperature of a cell, a charging voltage of a cell, and a current amount flowing from a cell to the AFE IC 120, which will be described later.

The charging switch 140 and the discharging switch 150 are connected in series on the HCP between the external terminal and the battery cell 110 to perform the charging and discharging operations of the battery pack 100. Each of the charging switch 140 and the discharging switch 150 may be configured as a field effect transistor (FET).

The AFE IC 120 is connected in parallel to the battery cell 110, and the charging switch 140 and the discharging switch 150, and is connected in series between the battery cell 110 and the micro-computer 130. The AFE IC 120 detects a voltage of the battery cell 110 and transfers the detected voltage to the micro-computer 130.

The micro-computer 130 is an integrated circuit that is connected in series between the AFE IC 120 and the external system, and controls the charging switch 140 and the discharging switch 150 to prevent over-charging, over-discharging, and/or excessive current from being transmitted through the battery cell 110. That is, the voltage of the battery cell 110 received through the AFE IC 120 is compared with a voltage level value set in the micro-computer 130, and then, the charging switch 140 and the discharging switch 150 are turned on or turned off by a control signal according to the comparison result in order to prevent or reduce occurrence of the battery cell 110 from over-charging or over-discharging. For example, when the voltage of the battery cell 110 transmitted to the micro-computer 130 is equal to or greater than an over-charging level voltage value set in the micro-computer 130, for example, 4.35V, the micro-computer 130 determines that the battery cell 110 is in an over-charged state, and outputs a corresponding control signal to turn the charging switch 140 off. Then, charging of the battery cell 110 is blocked. On the other hand, when the voltage of the battery cell 110 transmitted to the micro-computer 130 is equal to or lower than an over-discharging level voltage value set in the micro-computer 130, for example, 2.30V, the micro-computer 130 determines that the battery cell 110 is in an over-discharged state, and outputs a corresponding control signal in order to turn the discharging switch 150 off. Then, discharging from the battery cell 110 to the load is blocked. Here, the switching operations of the charging switch 140 or the discharging switch 150 are directly controlled by the micro-computer 130. However, in another embodiment, for example, the AFE IC 120 may control the switching operations of the charging switch 140 and the discharging switch 150 according to control by the micro-computer 130.

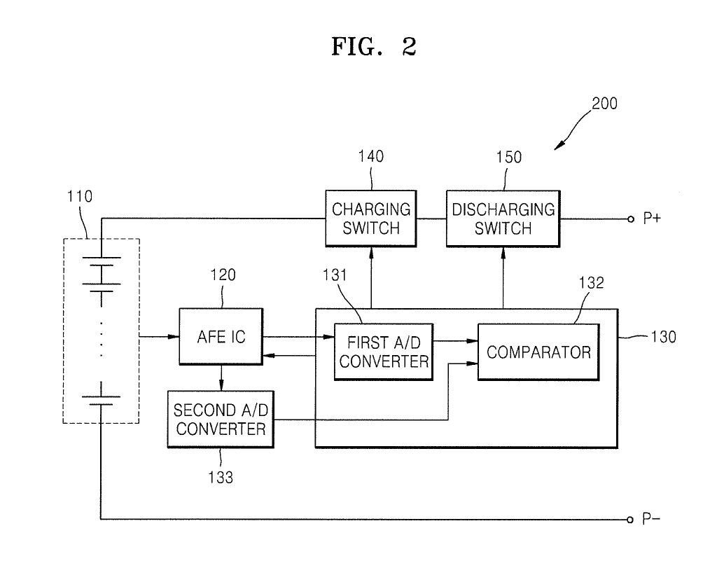

FIG. 2 is a circuit diagram of a battery pack 200 according to another embodiment of the present invention.

Referring to FIG. 2, the battery pack 200 includes the battery cell 110, external terminals P+ and P− connected to the battery cell 110 in parallel, the charging switch 140 and the discharging switch 150 connected to an HCP in series between the battery cell 110 and the external terminals, the AFE IC 120 connected to the battery cell 110 in parallel, the micro-computer 130, and a second analog/digital (A/D) converter 133. Here, the micro-computer 130 includes a first A/D converter 131 and a comparator 132.

The micro-computer 130 converts a physical input, for example, a voltage of the battery cell 110, that is, a voltage currently charged in the battery cell 110, into digital values by using the first and second A/D converters 131 and 133, and then compares the converted values to each other in order to determine whether the A/D conversion is normally performed. In addition, if an error or difference between the converted values is equal to or greater than a predetermined threshold value, the micro-computer 130 determines that there is a defect in the A/D conversion. The micro-computer 130 may further include a control terminal (not shown) for outputting a control signal corresponding to a process for handling the A/D conversion defect, and may, for example, turn off the charging switch 140 or the discharging switch 150 according to the A/D conversion defect. Therefore, generation of an error due to a defect in the A/D conversion when calculating a remaining amount of energy stored in the battery pack 100 may be prevented or reduced, and the A/D conversion defect may be handled or corrected before the protective circuit is improperly operated due to such an A/D conversion defect.

The first A/D converter 131 and the second A/D converter 133 respectively convert analog input values including a voltage, a temperature, and a current corresponding to the battery cell 110 into digital output values. Here, the first A/D converter 131 is disposed in the micro-computer 130, and the second A/D converter 133 is disposed outside of the micro-computer 130. However, the A/D converters may be arranged in various different configurations in other embodiments. When the battery pack 200 is used, the first A/D converter 131 is used as a main A/D converter and the second A/D converter 133 is used as an auxiliary A/D converter when the A/D conversion is determined to be operating normally according to the present embodiment.

In the present embodiment, the first A/D converter 131 and the second A/D converter 133 receive the voltage of the battery cell 110 measured by the AFE IC 120, that is, the voltage of the entire battery pack 200. In addition, the first and second A/D converters 131 and 133 may receive the cell temperature measured by a temperature sensor (not shown) disposed in the battery cell 110, and may convert the input value into digital values. In addition, the first and second A/D converters 131 and 133 may convert an amount of current transmitted through the battery cell 110 and sensed by a current sensor disposed on the HCP, for example, a shunt resistor (not shown), into digital values.

The comparator 132 compares a first output value output from the first A/D converter 131 and a second output value output from the second A/D converter 133. That is, the comparator 132 determines whether a difference between the first and second output values is equal to or greater than a first threshold value. Here, the first threshold value may be set arbitrarily. For example, when the difference is equal to or greater than, for example, three bits, the comparator 132 may determine that the A/D conversion has a defect.

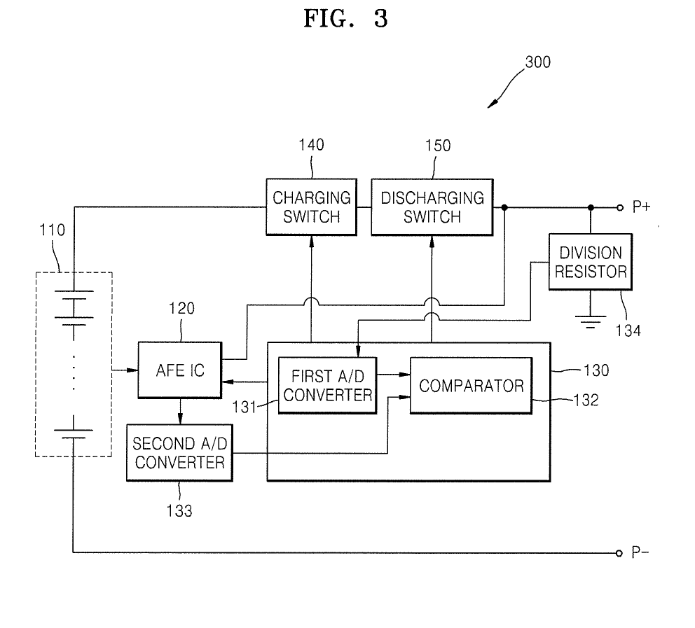

FIG. 3 is a circuit diagram of a battery pack 300 according to another embodiment of the present invention.

Referring to FIG. 3, the battery pack 300 according to the present embodiment is different form the battery pack 200 shown in FIG. 2 in that a voltage of the battery cell 110 output from the AFE IC 120 is divided by a division resistor 134, and the voltage of the battery cell 110 is input into the first A/D converter 131 through the division resistor 134. In addition, the first and second A/D converters 131 and 133 respectively convert the voltage of the battery cell 110 into digital output values, and the comparator 132 determines whether there is a defect in the A/D conversion by determining, for example, when an error or difference between the digital output values output from the first and second A/D converters 131 and 133 is equal to or greater than a threshold value.

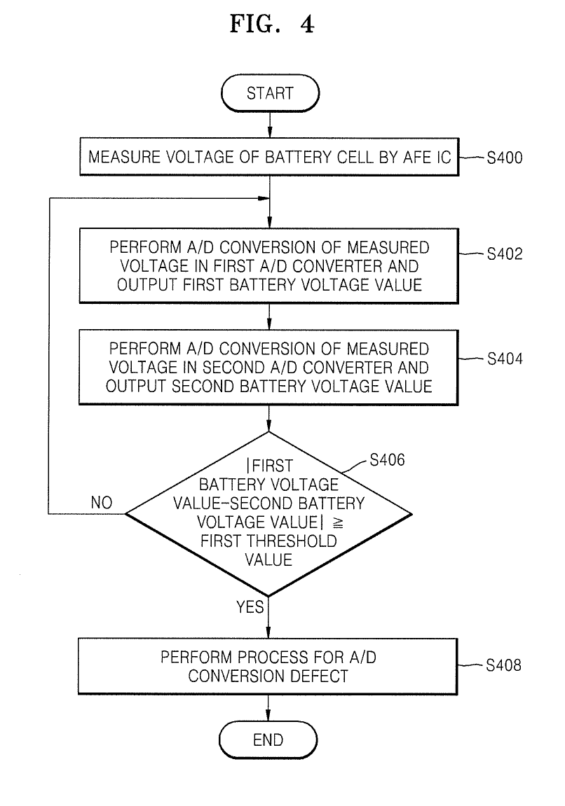

FIG. 4 is a flowchart illustrating a method of controlling a battery pack according to an embodiment of the present invention.

Referring to FIG. 4, in operation 400, an AFE IC measures a voltage of a battery cell. In operation 402, a first A/D converter converts the measured voltage of the battery cell into a digital value and outputs the digital value as a first battery voltage value. In operation 404, a second A/D converter converts the measured voltage of the battery cell into a digital value, and outputs the digital value as a second battery voltage value. Here, the first A/D converter is a main A/D converter built in a micro-computer of the battery pack, and the second A/D converter is an auxiliary A/D converter outside of the micro-computer. Operations 402 and 404 may be performed substantially simultaneously or sequentially, and the order in which the operations are performed is not limited thereto. In addition, while the voltage of the battery cell is discussed here, another physical input such as a temperature of the battery cell or an amount of current transmitted through the battery cell may also be converted into digital output values.

In operation 406, it is determined whether a difference between the first battery voltage value and the second battery voltage value is equal to or greater than a first threshold value. Then, if the difference is equal to or greater than the first threshold value, a process for handling the defect in the A/D conversion is performed in operation 408. Here, the first threshold value may be set arbitrarily, and may be determined in consideration of a desired accuracy in regards to sensing defects of the A/D conversion or the error. The process for handling the defect in the A/D conversion may include, for example, a process for outputting a control signal informing about or indicating an A/D conversion defect through a control terminal, or for example, a process of turning off a charging switch or a discharging switch in order to prevent or avoid improper operation of a protective circuit. Therefore, generation of an error due to a defect in the A/D conversion when calculating a remaining amount of energy stored in the battery pack may be prevented or reduced, and such A/D conversion defects may be more readily handled before the protective circuit is improperly operated due to such A/D conversion defects.

A battery pack according to embodiments of the present invention senses a fine difference between outputs of A/D conversion and may perform a process for detecting and/or handling an A/D conversion defect, and thus, an accumulation of state of charge (SOC) errors and improper operation of a protective circuit, where a micro-computer may recognize defective A/D conversions as normal A/D conversions, may be prevented or reduced.

In addition, embodiments of the present invention can also be implemented through computer readable code/instructions in/on a medium, e.g., a computer readable medium, to control at least one processing element to implement any of the above described embodiments. The medium can correspond to any medium/media permitting the storage and/or transmission of computer readable code.

The computer readable code can be recorded/transferred on a medium in a variety of ways, with examples of the medium including recordable media, such as magnetic storage media (e.g., ROM, floppy disks, hard disks, etc.) and optical recording media (e.g., CD-ROMs, or DVDs), and transmission media such as Internet transmission media. Thus, the medium may be such a defined and measurable structure including or carrying signals or information, such as a device carrying a bitstream, according to one or more embodiments of the present invention. The media may also be a distribution network, so that the computer readable code is stored/transferred and executed in a distributed fashion. Furthermore, the processing element could include a processor or a computer processor, and processing elements may be distributed and/or included in a single device.

According to a battery pack of embodiments of the present invention, a defect of A/D conversion is detected, and thus, generation of an error due to defects in the A/D conversion, for example, when calculating a remaining amount of energy stored in the battery pack, may be prevented or reduced, and the A/D conversion defects may be detected and/or handled before the protective circuit is improperly operated due to such A/D conversion defects.

It should be understood that the exemplary embodiments described herein should be considered in a descriptive sense only, and not for purposes of limitation. Descriptions of features or aspects within each embodiment should be considered as available for other similar features or aspects in other embodiments. It should also be understood that the invention is intended to cover various modifications and equivalent arrangements included within the spirit and scope of the appended claims, and equivalents thereof.

What is claimed is:

1. A battery pack comprising:
a battery cell;
a protective circuit for protecting the battery cell;
a first analog/digital (A/D) converter for converting a voltage of the battery cell into a digital value and outputting the digital value as a first voltage value;
a second A/D converter for converting the voltage of the battery cell into another digital value and outputting the another digital value as a second voltage value; and
a comparator for comparing the first voltage value with the second voltage value and determining whether A/D conversion of the battery pack is normal or defective according to the comparison.

2. The battery pack of claim 1, wherein the comparator is configured to determine that the A/D conversion is defective when a difference between the first voltage value and the second voltage value is equal to or greater than a threshold value.

3. The battery pack of claim 1, wherein the protective circuit comprises:
an analog front end (AFE) connected to the battery cell;
a computing device; and
a charging switch and a discharging switch respectively turned on or turned off according to control by the computing device.

4. The battery pack of claim 3, wherein the computing device comprises:
the first A/D converter for converting the voltage of the battery cell output from the AFE into the digital value and outputting the digital value as the first voltage value; and
the comparator for comparing the first voltage value output from the first A/D converter with the second voltage value output from the second A/D converter to determine whether the A/D conversion of the computing device is normal or defective.

5. The battery pack of claim 4, wherein the second A/D converter is configured to convert the voltage of the battery cell output from the AFE into the another digital value and to output the another digital value as the second voltage value to the comparator.

6. The battery pack of claim 4, wherein the computing device further comprises a control terminal for outputting a control signal indicating a defect in the A/D conversion of the computing device when a difference between the first voltage value and the second voltage value is equal to or greater than a threshold value.

7. The battery pack of claim 4, wherein the computing device is configured to output a control signal for turning off at least one of the charging switch or the discharging switch when a difference between the first voltage value and the second voltage value is equal to or greater than a threshold value.

8. The battery pack of claim 4, further comprising a division resistor for voltage dividing the voltage of the battery cell output from the AFE and outputting the divided voltage to the first A/D converter.

9. The battery pack of claim 1, wherein at least two battery cells are connected in series, and wherein the voltage of the battery cell comprises a voltage value of the at least two battery cells.

10. A battery pack comprising:
a plurality of battery cells;
an analog front end (AFE) connected to the plurality of battery cells;
a computing device; and
an A/D converter for converting an input signal from the plurality of battery cells output from the AFE into a digital value, and outputting the digital value as a first output value to the computing device,
wherein the computing device compares the first output value with a second output value comprising another digital value corresponding to the input signal from the plurality of battery cells output from the AFE, to determine whether A/D conversion of the battery pack is normal or defective.

11. The battery pack of claim 10, wherein the computing device is configured to determine that the A/D conversion is defective when a difference between the first output value and the second output value is equal to or greater than a threshold value.

12. The battery pack of claim 10, wherein the input signal from the plurality of battery cells is a voltage of the plurality of battery cells.

13. A method for controlling a battery pack comprising a plurality of battery cells; an AFE connected to the plurality of battery cells; and a computing device, the method comprising:
converting an input signal from the plurality of battery cells output from the AFE into a digital value and outputting the digital value as a first output value;
converting the input signal from the plurality of battery cells output from the AFE into another digital value and outputting the another digital value as a second output value;
comparing the first output value with the second output value; and
determining whether A/D conversion of the computing device is normal or defective according to the comparison.

14. The method of claim 13, wherein, in the determining operation, the A/D conversion is determined to be defective when a difference between the first output value and the second output value is equal to or greater than a threshold value.

15. The method of claim 13, further comprising outputting a control signal indicating a defect in the A/D conversion of the computing device when a difference between the first output value and the second output value is equal to or greater than a threshold value.

16. The method of claim 15, wherein the control signal is a signal for turning off at least one of a charging switch or a discharging switch respectively controlling charging and discharging operations of the battery pack.

17. The method of claim 13, wherein the input signal from the plurality of battery cells is a voltage of the plurality of battery cells.
